(19) United States
(12) Patent Application Publication
(10) Pub. No.: US 2024/0160100 A1
(43) Pub. Date: May 16, 2024

(54) INTEGRATED SOLUTION WITH LOW TEMPERATURE DRY DEVELOP FOR EUV PHOTORESIST

(71) Applicant: Applied Materials, Inc., Santa Clara, CA (US)

(72) Inventors: Tzu Shun Yang, Milpitas, CA (US); Zhenxing Han, Sunnyvale, CA (US); Madhur Sachan, Belmont, CA (US); Lequn Liu, San Jose, CA (US); Nasrin Kazem, Santa Clara, CA (US); Lakmal Charidu Kalutarage, San Jose, CA (US); Mark Joseph Saly, Milpitas, CA (US)

(21) Appl. No.: 18/222,897

(22) Filed: Jul. 17, 2023

Related U.S. Application Data
(60) Provisional application No. 63/466,891, filed on May 16, 2023.
(60) Provisional application No. 63/425,264, filed on Nov. 14, 2022.

(51) Int. Cl. G03F 7/004; G03F 7/00; G03F 7/16; G03F 7/36; H01L 21/027

(52) U.S. Cl. CPC G03F 7/0042; G03F 7/167; G03F 7/36; G03F 7/70033; H01L 21/0274

(57) ABSTRACT

Embodiments disclosed herein may include a method for developing a photopatterned metal oxo photoresist. In an embodiment, the method may include pre-treating the photopatterned metal oxo photoresist with a pre-treatment process, developing the photopatterned metal oxo photoresist with a thermal dry develop process to selectively remove a portion of the photopatterned metal oxo photoresist and form a resist mask. In an embodiment, the thermal dry develop process includes a first sub-operation, and a second sub-operation that is different than the first sub-operation. In an embodiment, the process further includes post-treating the resist mask with a post-treatment process.

### CROSS-REFERENCE TO RELATED APPLICATIONS

This application claims the benefit of U.S. Provisional Application No. 63/466,891, filed on May 16, 2023, and U.S. Provisional Application No. 63/425,264, filed on Nov. 14, 2022, the entire contents of which are hereby incorporated by reference herein.

### BACKGROUND

### 1) Field

Embodiments of the present disclosure pertain to the field of semiconductor processing and, in particular, to methods of developing a metal oxo photoresist using vapor phase processes.

### 2) Description of Related Art

Lithography has been used in the semiconductor industry for decades for creating 2D and 3D patterns in microelectronic devices. The lithography process involves spin-on deposition of a film (photoresist), irradiation of the film with a selected pattern by an energy source (exposure), and removal (etch) of exposed (positive tone) or non-exposed (negative tone) region of the film by dissolving in a solvent. A bake will be carried out to drive off remaining solvent.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist is removed (etched). Now the photoresist is developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

### SUMMARY

Embodiments disclosed herein may include a method for developing a photopatterned metal oxo photoresist. In an embodiment, the method may include pre-treating the photopatterned metal oxo photoresist with a pre-treatment process, developing the photopatterned metal oxo photoresist with a thermal dry develop process to selectively remove a portion of the photopatterned metal oxo photoresist and form a resist mask, and post-treating the resist mask with a post-treatment process.

Embodiments disclosed herein may also include a semiconductor processing tool. In an embodiment, the semiconductor processing tool may include a transfer chamber, where a substrate handling robot is provided in the transfer chamber. The tool may further include a first processing chamber fluidically coupled to the transfer chamber, where the first processing chamber is configured to deposit a metal oxo resist on a substrate with a dry deposition process. The tool may further include a second processing chamber fluidically coupled to the transfer chamber, where the second processing chamber is configured to pre-treat or post-treat the metal oxo resist with a thermal treatment, an irradiation treatment, and/or a plasma treatment. The tool may further include a third processing chamber fluidically coupled to the transfer chamber, where the third processing chamber is configured to develop the metal oxo resist with a dry develop process.

### BRIEF DESCRIPTION OF THE DRAWINGS

FIG. 1A is a flowchart describing a process for treating and developing a metal oxo photoresist, in accordance with an embodiment.

FIG. 1B is a flowchart describing a process for depositing, treating, and developing a metal oxo photoresist, in accordance with an embodiment.

FIG. 2 is a flowchart describing a process for developing a metal oxo photoresist using a vapor phase process with a halogenating agent, in accordance with an embodiment of the present disclosure.

FIGS. 3A-3C are cross-sectional illustrations of a substrate and a photoresist depicting operations in the flowchart of FIG. 2, in accordance with an embodiment of the present disclosure.

FIG. 4 is a flowchart describing a process for developing a metal oxo photoresist using a vapor phase process with a halogenating agent and a protonated ligand, in accordance with an embodiment of the present disclosure.

FIGS. 5A-5C are cross-sectional illustrations of a substrate and a photoresist depicting operations in the flowchart of FIG. 4, in accordance with an embodiment of the present disclosure.

FIG. 6 is a flowchart describing a process for developing a metal oxo photoresist using a vapor phase process with an organic acid, in accordance with an embodiment of the present disclosure.

FIGS. 7A and 7B are cross-sectional illustrations of a substrate and a photoresist depicting operations in the flowchart of FIG. 6, in accordance with an embodiment of the present disclosure.

FIG. 8A is a cross-sectional illustration of a processing tool that may be used to implement portions of the process in FIG. 1, FIG. 2, FIG. 4, or FIG. 6, in accordance with an embodiment of the present disclosure.

FIG. 8B is a plan view schematic of a cluster tool that may be used to process metal oxo photoresists, in accordance with an embodiment of the present disclosure.

FIG. 9 illustrates a block diagram of an exemplary computer system, in accordance with an embodiment of the present disclosure.

### DETAILED DESCRIPTION

Methods of developing a metal oxo photoresist using vapor phase processes are described herein. In the following description, numerous specific details are set forth, such as thermal vapor phase processes and material regimes for developing photoresist, in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. Organic-inorganic hybrid materials (e.g., metal oxo materials systems) have been proposed as a material system for EUV lithography due to the increased sensitivity to EUV radiation. Such material systems typically include a metal (e.g., Sn, Hf, Zr, etc.), oxygen, and carbon. Metal oxo based organic-inorganic hybrid materials have also been shown to provide lower LER and higher resolution, which are required characteristics for forming narrow features.

In a metal oxo photoresist system, exposure to EUV radiation results in the removal of carbon. The difference in the carbon percentage between the exposed regions and the unexposed regions is used as the solubility switch during developing. Particularly, the unexposed regions with the higher carbon content are preferentially etched by the developer solution in a negative tone develop.

Metal oxo photoresist systems are currently developed using a wet chemistry. That is, after exposure, the unexposed regions of the photoresist are developed by organic solvents/base solution that is used with a spin-dry process. A post-bake anneal may also be included. However, wet methods can be troublesome when dealing with high aspect ratio features due to the risk of pattern collapse (especially in line or pillar structures). Additionally, wet processes might not remove all of the material that is supposed to be removed and film materials/byproducts/solvents and the like may be trapped in small features.

Accordingly, embodiments of the present disclosure provide a vapor phase thermal etching process to develop metal oxo photoresists. Particularly, vapor phase thermal etching processes provide the advantages of: 1) eliminating the generation of wet byproducts; 2) providing fewer defects and impurities; 3) lower waste streams due to dry chemistry being destroyed in an abatement system; 4) improvement of LER; and 5) less damage with dry thermal etch when compared to plasma damage in reactive ion etching (RIE). For example, at a pitch less than 30 nm (e.g., line CD less than 14 nm) and less than 15 nm photoresist thickness, a plasma can potentially damage the photoresist mask which may result in poor LER/LWR or even a broken line pattern when the pattern is transferred to the underlayer.

Embodiments disclosed herein provide various vapor phase thermal etching processes that are executed after portions of a metal oxo photoresist are exposed with a suitable electromagnetic radiation source (e.g., an EUV source). In a first embodiment, the vapor phase thermal etching process includes vaporizing a halogenating agent into a vacuum chamber. The halogenating agent reacts with either the unexposed or exposed regions of the photoresist to produce a volatile byproduct that is removed from the vacuum chamber. In a second embodiment, the vapor phase thermal etching process includes vaporizing a halogenating agent into a vacuum chamber. The halogenating agent may react with either the unexposed or exposed regions of the photoresist to produce a non-volatile product. A ligand may then be vaporized into the chamber, and the ligand reacts with the non-volatile product to provide a volatile byproduct that can be removed from the vacuum chamber. In a third embodiment, the vapor phase thermal etching process includes vaporizing an organic acid into a vacuum chamber. The organic acid reacts with either the unexposed or exposed regions of the photoresist to produce a volatile byproduct that is removed from the vacuum chamber.

In embodiments disclosed herein, the dry develop processes may be implemented after a pre-treatment is applied to the metal oxo photoresist. The pretreatment may include thermal treatments, irradiation treatments, and/or plasma treatments. Additionally, embodiments may include post-treatments after the dry develop process. The post-treatments may include thermal treatments, irradiation treatments, and/or plasma treatments.

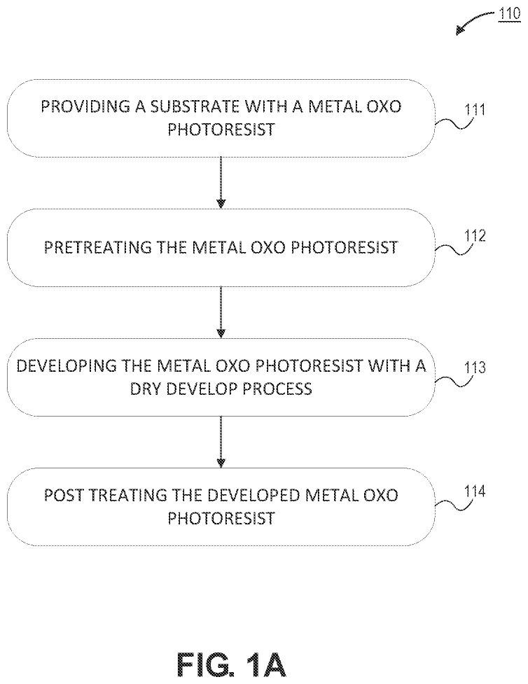

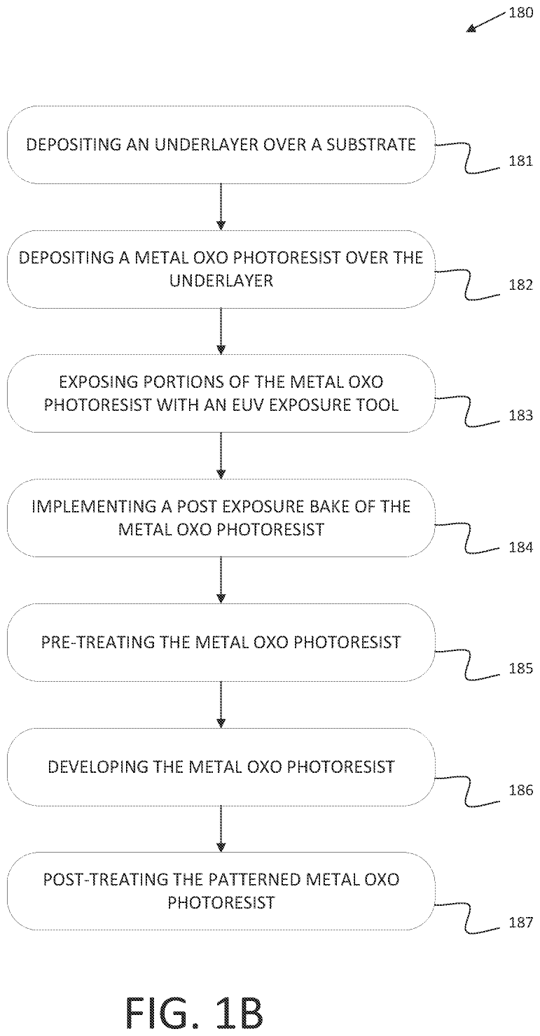

Referring now to FIG. 1A, a process flow diagram depicting a process 110 for developing a metal oxo photoresist is shown, in accordance with an embodiment. In an embodiment, process 110 may begin with operation 111, which includes providing a substrate with a metal oxo photoresist. The photoresist may be disposed over the surface of the substrate using any suitable deposition process. In an embodiment, the photoresist is disposed on the surface of the substrate with a wet chemistry using a spin-on process. In an alternative embodiment, the photoresist is disposed on the surface of the substrate using a vapor phase process (i.e., a dry process). In a vapor phase process, a metal precursor and an oxidant may be vaporized to a vacuum chamber, with the metal precursor and the oxidant reacting to deposit a metal oxo photoresist on the surface of the substrate. Such dry processes may be characterized as a chemical vapor deposition (CVD) process, an atomic layer deposition (ALD) process, a plasma enhanced CVD (PE-CVD) process, or a plasma enhanced ALD (PE-ALD) process.

In an embodiment, the process 110 may include an exposure step after the metal oxo photoresist is deposited. The exposure step (e.g., an EUV exposure) converts exposed regions of the metal oxo photoresist into a material that can be selectively etched with respect to the unexposed regions. The EUV exposure may be made through a mask layer, or through reflection off of a mask layer. While referred to as EUV, it is to be appreciated that other wavelengths (e.g., deep ultraviolet (DUV) or ultraviolet (UV) wavelengths) may also be used in some embodiments.

In an embodiment, after the metal oxo photoresist is provided on the substrate and exposed to EUV, the process 110 may continue with operation 112. Operation 112 may include pretreating the metal oxo photoresist. Pretreating operations may occur before exposure and/or development of the metal oxo photoresist. In an embodiment, the pretreatment may include one or more of a thermal treatment, an irradiation treatment, and a plasma treatment.

In the case of a thermal treatment, the photoresist may be exposed to temperatures between approximately −100 degrees Celsius and approximately 300 degrees Celsius. The duration of the thermal treatment may be between approximately 0.1 seconds and approximately 600 seconds. In an embodiment, the thermal treatment may be implemented in an ambient that includes one or more gases. For example, the gases may include O₂, N₂, CO₂, H₂, D₂, H₂O, D₂O, Ar, He, Cl₂, Br₂, I₂ HCl, HBr, HI, CH₄, TDMA-Me (where Me includes Sn, Zr, Al, Hf, Cr, Ta, Ru, Mo, Te, Ti, Zn, etc.), NH₄X (X=F, CL, Br or I) and in particular NH₄Cl, or combinations thereof.

In the case of an irradiation treatment, the metal oxo photoresist may be exposed to electromagnetic radiation of a particular wavelength. For example, the wavelength may be between approximately 150 nm and approximately 700 nm. The irradiation treatment may be implemented in an ambient that includes one or more gases. For example, the gases may include O₂, N₂, CO₂, H₂, D₂, H₂O, D₂O, Ar, He, Cl₂, Br₂, I₂, HCl, HBr, HI, CH₄, TDMA-Me (where Me includes Sn, Zr, Al, Hf, Cr, Ta, Ru, Mo, Te, Ti, Zn, etc.), NH₄X (X=F, CL, Br or I) and in particular NH₄Cl, or combinations thereof.

In the case of a plasma treatment, the plasma may include a plasma from a source gas of H₂, D₂, Ar, and/or He. The flow rate of the one or more gases may be between approximately 1 sccm and approximately 2,000 sccm. A pressure of the chamber may be between approximately 1 mTorr to approximately 500 mTorr. Source power may be supplied at OW to 3,000 W using inductively coupled plasma (ICP), capacitively coupled plasma (CCP), or transformer coupled plasma (TCP). Bias power may be between OW and 1,000 W using 13 MHz and/or 2 MHz frequencies.

In an embodiment, the process 110 may continue with operation 113, which includes developing the metal oxo photoresist with a dry develop process, such as a vapor phase thermal etching process. In a first embodiment, the vapor phase thermal etching process includes vaporizing a halogenating agent into a vacuum chamber. The halogenating agent reacts with either the unexposed or exposed regions of the photoresist to produce a volatile byproduct that is removed from the vacuum chamber. In a second embodiment, the vapor phase thermal etching process includes vaporizing a halogenating agent into a vacuum chamber. The halogenating agent may react with either the unexposed or exposed regions of the photoresist to produce a non-volatile product. A ligand may then be vaporized into the chamber, and the ligand reacts with the non-volatile product to provide a volatile byproduct that can be removed from the vacuum chamber. In a third embodiment, the vapor phase thermal etching process includes vaporizing a halogen containing inorganic/organic acid into a vacuum chamber. The halogen containing acid(s) react with either the unexposed or exposed regions of the photoresist to produce a volatile byproduct that is removed from the vacuum chamber. More detailed explanations of the vapor phase thermal etching processes are described in greater detail below.

In an embodiment, the process 110 may continue with operation 114, which includes post treating the developed metal oxo photoresist. In an embodiment, the post treatment may include a thermal treatment, an irradiation treatment, and/or a plasma treatment.

In the case of a thermal treatment, the photoresist may be exposed to temperatures between approximately −100 degrees Celsius and approximately 300 degrees Celsius. The duration of the thermal treatment may be between approximately 0.1 seconds and approximately 600 seconds. In an embodiment, the thermal treatment may be implemented in an ambient that includes one or more gases. For example, the gases may include O₂, N₂, CO₂, H₂, D₂, H₂O, D₂O, Ar, He, Cl₂, Br₂, I₂, HCl, HBr, HI, CH₄, TDMA-Me (where Me includes Sn, Zr, Al, Hf, Cr, Ta, Ru, Mo, Te, Ti, Zn, etc.), NH₄X (X=F, CL, Br or I) and in particular NH₄Cl, or combinations thereof.

In the case of an irradiation treatment, the metal oxo photoresist may be exposed to electromagnetic radiation of a particular wavelength. For example, the wavelength may be between approximately 150 nm and approximately 700 nm. The irradiation treatment may be implemented in an ambient that includes one or more gases. For example, the gases may include O₂, N₂, CO₂, H₂, D₂, H₂O, D₂O, Ar, He, Cl₂, Br₂, I₂, HCl, HBr, HI, CH₄, TDMA-Me (where Me includes Sn, Zr, Al, Hf, Cr, Ta, Ru, Mo, Te, Ti, Zn, etc.), NH₄X (X=F, CL, Br or I) and in particular NH₄Cl, or combinations thereof.

In the case of a plasma treatment, the plasma may include a plasma from a source gas of H₂, D₂, Ar, and/or He. The flow rate of the one or more gases may be between approximately 1 sccm and approximately 2,000 sccm. A pressure of the chamber may be between approximately 1 mTorr to approximately 500 mTorr. Source power may be supplied at OW to 3,000 W using ICP, CCP, or TCP. Bias power may be between OW and 1,000 W using 13 MHz and/or 2 MHz frequencies.

In an embodiment, the process 100 may include pre-treatments that are substantially similar to the post treatments. In other embodiments, the pre-treatment may be different than the post treatment. For example, the pre-treatment may include a thermal treatment, and the post-treatment may include a plasma treatment. Though, it is to be appreciated that any combination of pre-treatment operations and any combination of post-treatment operations may be used in order to improve the performance of the metal oxo photoresist.

Referring now to FIG. 1B, a process flow diagram of a process 180 is shown, in accordance with an embodiment. In an embodiment, the process 180 may begin with operation 181, which includes depositing an underlayer over a substrate. The underlayer may be a material that improves the performance of an overlying metal oxo resist. For example, the underlayer may be an adhesion promoting layer. In other embodiments, the underlayer may improve imaging quality of the overlying metal oxo resist. The underlayer may be considered a high Z metal oxide.

In an embodiment, the process 180 may then continue with operation 182, which includes depositing a metal oxo photoresist over the underlayer. In an embodiment, the metal oxo photoresist may be deposited with a wet process (e.g., spin coating, etc.). In other embodiments, a dry deposition process such as a vapor phase process is used to form the metal oxo photoresist. In a vapor phase process, a metal precursor and an oxidant may be vaporized to a vacuum chamber, with the metal precursor and the oxidant reacting to deposit a metal oxo photoresist on the surface of the substrate. Such dry processes may be characterized as a CVD process, an ALD process, a PE-CVD process, or a PE-ALD process.

In an embodiment, the process 180 may then continue with operation 183, which includes exposing portions of the metal oxo photoresist with an EUV exposure tool. In an embodiment, the EUV exposure may result in a chemical change in the composition of the metal oxo photoresist. The chemical change may result in a solubility switch being activated in order to enable selective etching of the exposed regions of the metal oxo photoresist relative to the unexposed regions of the metal oxo photoresist. While EUV exposure is described in greater detail herein, it is to be appreciated that DUV or UV exposure may also be used in some embodiments.

In an embodiment, the process 180 may then continue with operation 184, which includes implementing a post exposure bake (PEB) of the metal oxo photoresist. In an embodiment, the PEB may include raising the temperature of the substrate above a certain temperature (e.g., 100 degrees Celsius) and holding for a desired period of time. The elevated temperatures may allow for the chemical reaction initiated by the EUV exposure to proceed further. In other embodiments, the PEB may be used to drive off solvents or other constituents of the metal oxo photoresist.

In an embodiment, the process 180 may then continue with operation 185, which includes pre-treating the metal oxo photoresist. The pre-treatment process may be similar to the pre-treatment process described in greater detail above with respect to FIG. 1A. For example, the pre-treatment process may include a thermal treatment, an irradiation treatment, and/or a plasma treatment.

In an embodiment, the process 180 may then continue with operation 186, which includes developing the metal oxo photoresist. The developing process may be a dry developing process. For example, processing gases that include a halogenating agent, a halogenating agent and a ligand, or an organic acid may be flown into a chamber in order to develop the exposed metal oxo photoresist.

In a particular embodiment, the dry develop process may include two or more sub-operations. For example, a first sub-operation may be followed by a second sub-operation. The first sub-operation may be different than the second sub-operation. The differences between the sub-operations may include one or more different process parameters.

In one embodiment, a pressure of the first sub-operation may be different than a pressure of the second sub-operation. The first sub-operation may be at a lower pressure than the second sub-operation. For example, the first sub-operation may be implemented at a pressure below approximately 100 mTorr, and the second sub-operation may be implemented at a pressure above approximately 100 mTorr. In a particular embodiment, the first sub-operation may be implemented at a pressure of approximately 60 mTorr or lower, and the second sub-operation may be implemented at a pressure of approximately 350 mTorr or higher. In yet another embodiment, the first sub-operation may be at a higher pressure than the second sub-operation.

In an embodiment a temperature process parameter may be different between the first sub-operation and the second sub-operation. For example, the first sub-operation may be at a lower temperature than the second sub-operation. Though, in other embodiments, the first sub-operation may be at a higher temperature than the second sub-operation. In an embodiment, the temperature ranges for the first sub-operation and the second sub-operation may be between approximately −90 degrees Celsius and approximately 350 degrees Celsius. More specifically, temperature ranges may be between approximately −90 degrees Celsius and 50 degrees Celsius.

In yet another embodiment, a gas flow ratio may be varied between the first sub-operation and the second sub-operation. In the case of a two gas system, a first gas may have a flow rate between approximately 100 sccm and approximately 1,000 sccm, and the second gas may have a flow rate between 0 sccm and approximately 1,000 sccm. For example, a first ratio in the first sub-operation may be approximately 1:1, and a second ratio in the second sub-operation may be approximately 10:1. While various gases can be used (as will be described in greater detail below), two specific gases may include HBr for the first gas and Ar for the second gas.

In an embodiment, the duration of sub-operations may be different. For example, the first sub-operation may have a duration that is longer or shorter than a duration of the second sub-operation. Durations of the different sub-operations may range from approximately 1 second to approximately 10 minutes. In a particular embodiment, the first sub-operation may have a duration of approximately 60 seconds and the second sub-operation may have a duration of approximately 30 seconds.

In an embodiment, the sub-operations may be sequential. That is, the first sub-operation is followed by the second sub-operation. After the final sub-operation (e.g., the second sub-operation, a third sub-operation, etc.) the process 180 may continue on with the next operation 187. However, in other embodiments the sub-operations are looped any number of times. In such instances, after the final sub-operation is completed, the process 180 loops back to the first sub-operation. This sequence may be repeated for any number of cycles. For example, two or more cycles, or ten or more cycles may be used.

In an embodiment, the process 180 may then continue with operation 187, which includes post-treating the patterned metal oxo photoresist. In an embodiment, the post-treatment may be substantially similar to any of the post-treatments described in greater detail above. For example, the post-treatment may include a thermal treatment, an irradiation treatment, and/or a plasma treatment. In a particular embodiment, the post-treatment is different than the pre-treatment. In other embodiments, the post-treatment is substantially similar to the pre-treatment.

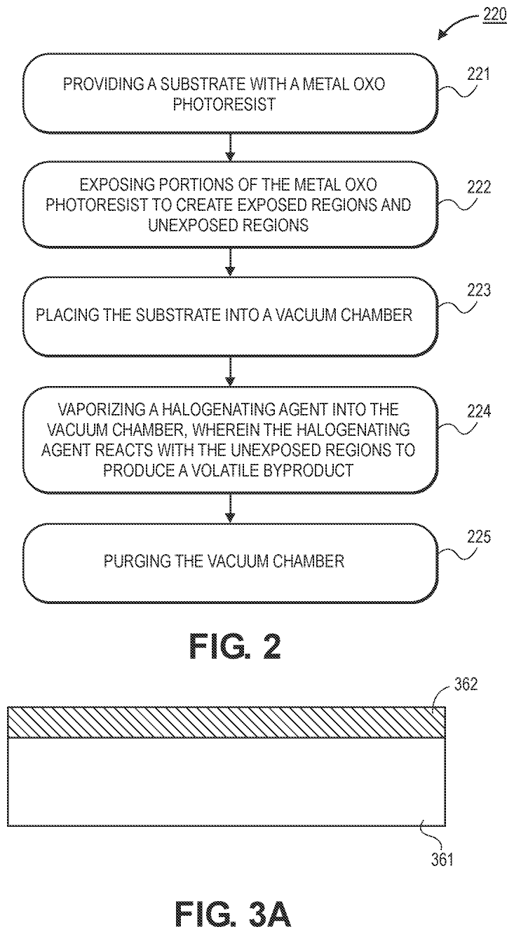

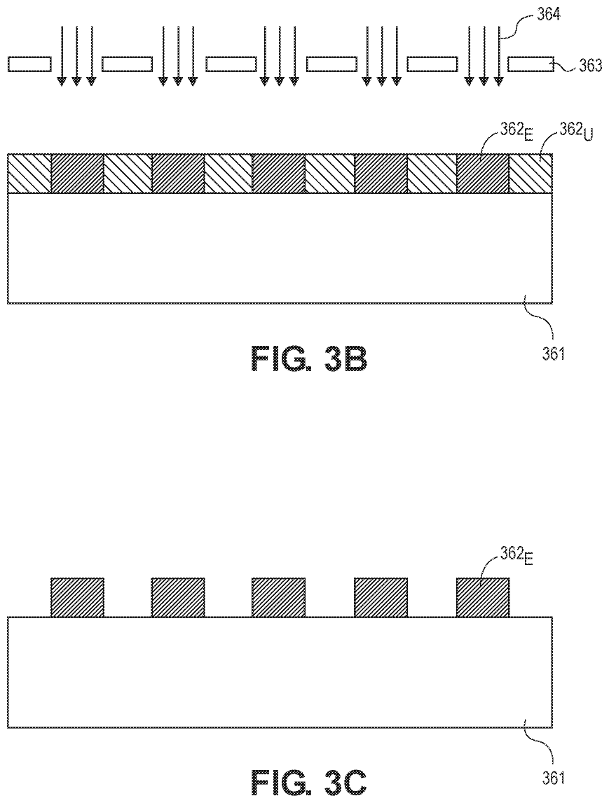

Referring now to FIG. 2, a flowchart illustrating a process 220 for developing a metal oxo photoresist on a substrate surface is provided, in accordance with an embodiment of the present disclosure. FIGS. 3A-3C are cross-sectional illustrations of a substrate 361 and a metal oxo photoresist 362 after various operations in process 220.

In an embodiment, process 220 may begin with operation 221 which includes providing a substrate with a metal oxo photoresist. FIG. 3A is a cross-sectional illustration of a substrate 361 with a metal oxo photoresist 362 disposed over a surface of the substrate 361. In an embodiment, the substrate 361 may include any substrate material or materials typical of semiconductor manufacturing environments. For example, the substrate 361 may include a semiconducting material. Substrate 361 may include semiconductor devices or portions of semiconductor devices. Examples of such semiconductor devices include, but are not limited to, memory devices or complimentary metal-oxide-semiconductor (CMOS) transistors fabricated in a silicon substrate and encased in a dielectric layer. The substrate 361 may also include a plurality of metal interconnects formed above the devices or transistors, and in surrounding dielectric layers, and may be used to electrically couple the devices or transistors to form integrated circuits. In an embodiment, the substrate 361 may be a wafer.

In an embodiment, the metal oxo photoresist 362 (also referred to simply as “photoresist 362”), may be any metal oxo material system. Such material systems typically include a metal (e.g., Sn, Zr, Al, Hf, Cr, Ta, Ru, Mo, Te, Ti, Zn etc.), oxygen, and carbon. In a particular embodiment, the photoresist 362, includes SnOC. In a more general sense, the photoresist 362 may include a structure of the form (RₐM)_{b}O_{c}(OH)_{d} where R is a ligand and M is a metal. In an embodiment, a is less than or equal to b, and b is between 2 and 125. In an embodiment, c+d is less than or equal to b, and x is 2 to 8.

The photoresist 362 may be disposed over the surface of the substrate 361 using any suitable deposition process. In an embodiment, the photoresist is disposed on the surface of the substrate 361 with a wet chemistry using a spin-on process. In an alternative embodiment, the photoresist is disposed on the surface of the substrate 361 using a vapor phase process (i.e., a dry process). In a vapor phase process, a metal precursor and an oxidant may be vaporized to a vacuum chamber, with the metal precursor and the oxidant reacting to deposit a metal oxo photoresist 362 on the surface of the substrate 261. Such dry processes may be characterized as a chemical vapor CVD process, an ALD process, a PE-CVD process, or a PE-ALD process.

In an embodiment, process 220 may continue with operation 222 which includes exposing portions of the metal oxo photoresist to create exposed regions and unexposed regions. FIG. 3B is a cross-sectional illustration depicting the exposure process. As shown, electromagnetic radiation 364 passes through a mask 363 to expose the exposed regions 362_{E}. The unexposed regions 362_{U} are blocked from the electromagnetic radiation by the mask 363. In an embodiment, the electromagnetic radiation is EUV radiation. When EUV radiation is used, the EUV radiation 364 may be reflected off the mask instead of passing through the mask. While EUV radiation specifically disclosed herein, it is to be appreciated that any suitable wavelength of electromagnetic radiation that can initiate a solubility switch in the metal oxo photoresist 362 may be used. For example, DUV radiation may be used in some embodiments.

In an embodiment, the solubility switch is provided by the loss of carbon. Particularly, the exposure to electromagnetic radiation results in the removal of carbon from the exposed regions 362_{E}. The higher carbon content in the unexposed regions 362_{U} renders the unexposed regions more susceptible to etching in the subsequent vapor phase development process.

In an embodiment, process 220 may continue with operation 223 which includes placing the substrate into a vacuum chamber. In an embodiment, the vacuum chamber may be any suitable chamber for providing sub-atmospheric pressure conditions. The vacuum chamber may also include heating/cooling features to provide thermal control of the vapor phase process. For example, a pedestal on which the substrate 361 is placed may be an actively heated and/or cooled pedestal. Additionally, walls of the vacuum chamber may be actively heated and/or cooled in some embodiments.

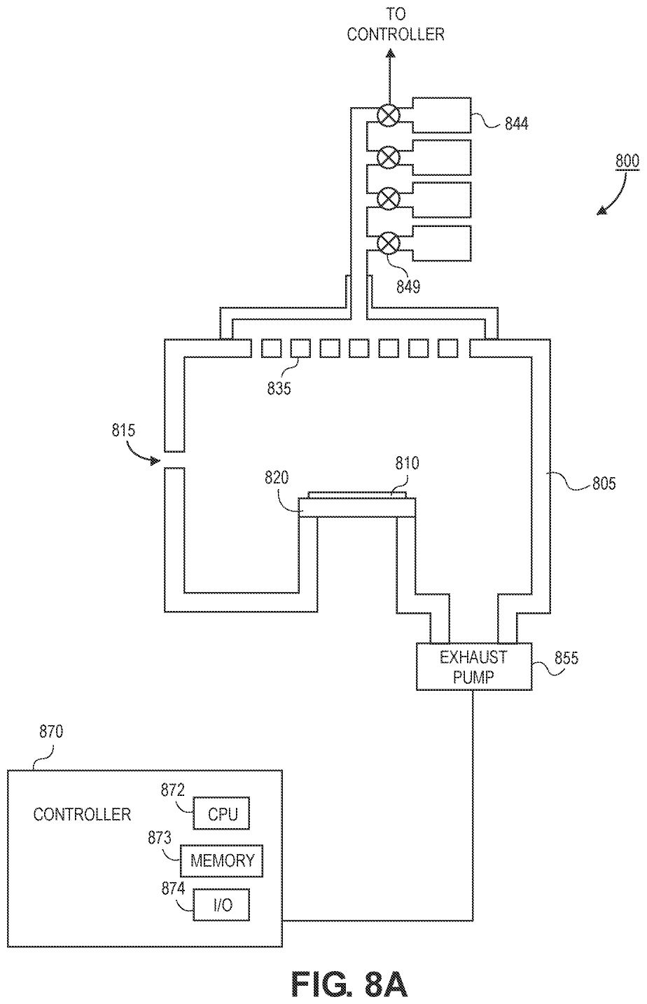

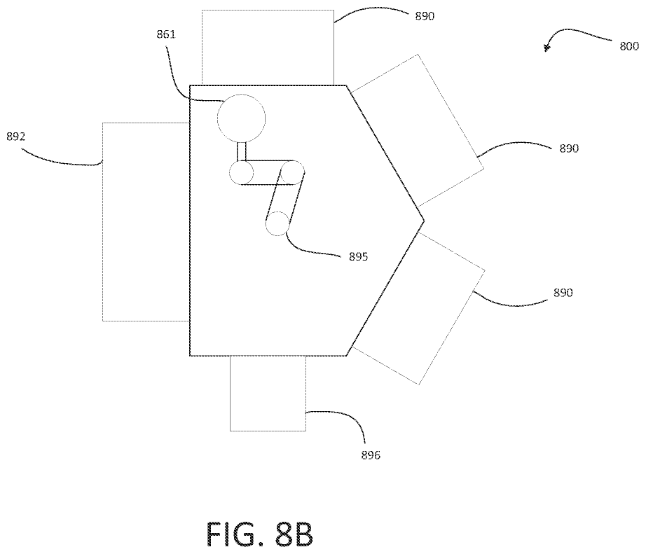

Particularly, it is to be appreciated that embodiments disclosed herein do not require a plasma source in order to implement the vapor phase etching of the metal oxo photoresist. Accordingly, the construction of the vacuum chamber may be simplified compared to processes that include plasma based developing of the metal oxo photoresist. A more detailed description of a suitable vacuum chamber is provided below with respect to FIG. 8.

In an embodiment, process 220 may continue with operation 224 which includes vaporizing a halogenating agent into the vacuum chamber. In an embodiment, the halogenating agent reacts with the unexposed regions 362_{U} to produce a volatile byproduct. That is, the reaction between the halogenating agent and the unexposed regions 362_{U} results in the removal of the unexposed regions 362_{U} from the substrate 361, as shown in FIG. 3C. In other embodiments, the halogenating agent may react with the exposed regions 362_{E} to produce a volatile byproduct. In an embodiment, the byproduct of the reaction is a volatile metal halide. Some metal halides have higher volatilities than others. For example SnCl₄ has a higher volatility than SnCl₂, CoClL (where L is a ligand) has a higher volatility than CoCl₂, and MoOCl₄ has a higher volatility than MoCl₅. Accordingly, the reaction may preferentially result in the formation of byproducts with higher volatilities. In an embodiment the byproducts may have the chemical formula RMXₓ, RMO_{y}Xₓ, or MX_{X} where M is a metal or semimetal, X is a halide, R is a ligand, x is 1-6 and y is 1-5.

In an embodiment, the halogenating agent is a metal halide with a formula MXₐ or MXₐL_{b}, where M is a metal or semimetal (e.g., Mo, W, Ta, Nb, Sn, V, Ti, or Si), X is a halide (e.g., Cl or Br), L is a volatile ligand (e.g., alkyls, ethylenediamine, or Cp), a is 1-6 and b is 1-5. For example, the metal halide may include MoCl₅, TaCl₅, NbCl₅, or WCl₅.

In an additional embodiment, the halogenating agent is a metal oxy halide with a formula MOₐX_{b} or MOₐX_{b}L_{c}, where M is a metal or semimetal (e.g., Mo, W, Ta, Nb, Sn, V, Ti, or Si), X is a halide (e.g., Cl or Br), L is a volatile ligand (e.g., alkyls ethylenediamine, or Cp), a is 1-5, b is 1-5, and c is 1-5. For example, the metal oxy halide may include MoOCl₄, MoO₂Cl₂, WOCl₄, or WO₂Cl₂.

In yet another additional embodiment, the halogenating agent may be an organic halogenating agent. For example, the halogenating agent may include thionyl chloride (SOCl₂), methanesulfonyl chloride (CH₃SO₂Cl), trichloromethanesulfonyl chloride (CCl₃SO₂Cl), 4-toluenesulfonyl chloride (tosyl chloride), oxalyl chloride (ClCOCOCl), tert-butyl hypochlorite ((CH₃)₃COCl), N-chlorophthalimide, 1,3-dichloro-5,5-dimethylhydantoin, trimethylsilyl chloride, HCl, Cl₂, PCl₅, BCl₃, HBr, Br₂, CCl₃Br, CBr₄, 1,2-dibromo-1,1,2,2-tetrachloroethane (Cl₂CBrCBrCl₂), BBr₃, PBr₃, N-bromosuccinimide, N-bromoacetamide, 2-bromo-2-cyano-N,N-dimethylacetamide, 1,3-dibromo-5,5-dimethylhydantoin, 2,4,4,6-tetrabromo-2,5-cyclohexadienone, or trimethylsilyl bromide.

In yet another embodiment, the halogenating agent may include one or more of SOBr₂ (thionyl bromide), SO₂Cl₂ (sulfuryl chloride), and SO₂Br₂ (sulfuryl bromide).

In an embodiment, the halogenating agent may be diluted with an inert gas. For example, inert gases such as Ar, N₂, or He may be used to dilute the halogenating agent. In other embodiments, gases such as O₂, N₂, CO₂, H₂, D₂, H₂O, D₂O, Ar, He, Cl₂, Br₂, I₂, HCl, HBr, HI, CH₄, TDMA-Me (where Me includes Sn, Zr, Al, Hf, Cr, Ta, Ru, Mo, Te, Ti, Zn, etc.), NH₄X (X=F, CL, Br or I) and in particular NH₄Cl, or combinations thereof may also be mixed with the halogenation agent. Generally, it has been shown that the etch selectivity of the unexposed regions of the photoresist 362_{U} relative to the exposed regions of the photoresist 362_{E} increases with increases in pressure. In an embodiment, the pressure may be between approximately 1 torr and approximately 100 torr. In a particular embodiment, the pressure may be between approximately 3 torr and approximately 10 torr. In an additional embodiment, the flow rate of gases may be between 1 sccm and 2,000 sccm, and a pressure may be between 1 mTorr and 500 mTorr.

In an embodiment, the substrate 361 may have a controlled temperature during operation 224. For example, the temperature may vary between approximately −90° C. and approximately 350° C. In a particular embodiment, the temperature may vary between approximately −90° C. and approximately −60° C. In an embodiment, source power may range between OW and 3,000 W using ICP, CCP, or TCP tools. In an embodiment, bias power may be between OW and 1,000 W at frequencies of approximately 13 MHz or approximately 2 MHz, for example.

In an embodiment, operation 224 may be implemented through the use of two or more sub-operations, similar to embodiments described in greater detail above. For example, a first sub-operation and a second sub-operation may include different processing parameters, such as, but not limited to, duration, pressure, temperature, and gas ratios. In other embodiments, the sub-operations may be looped for any number of cycles in order to complete operation 224.

In an embodiment process 220 may continue with operation 225 which includes purging the vacuum chamber. Purging the vacuum chamber removes the byproducts from the reaction in operation 224 from the vacuum chamber. In an embodiment, operation 224 may be implemented as a soak followed by a single purge in operation 225. In alternative embodiments, operations 224 and 225 may define a cycle including a pulse of the halogenating agent followed by a purge. In such embodiments, a plurality of cycles may be repeated in order to clear the unexposed regions of the photoresist 362_{U}.

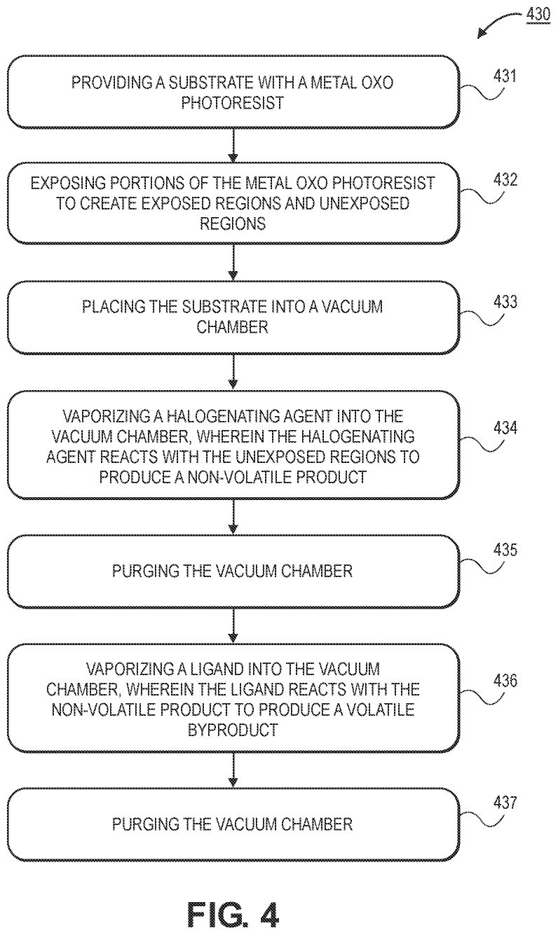

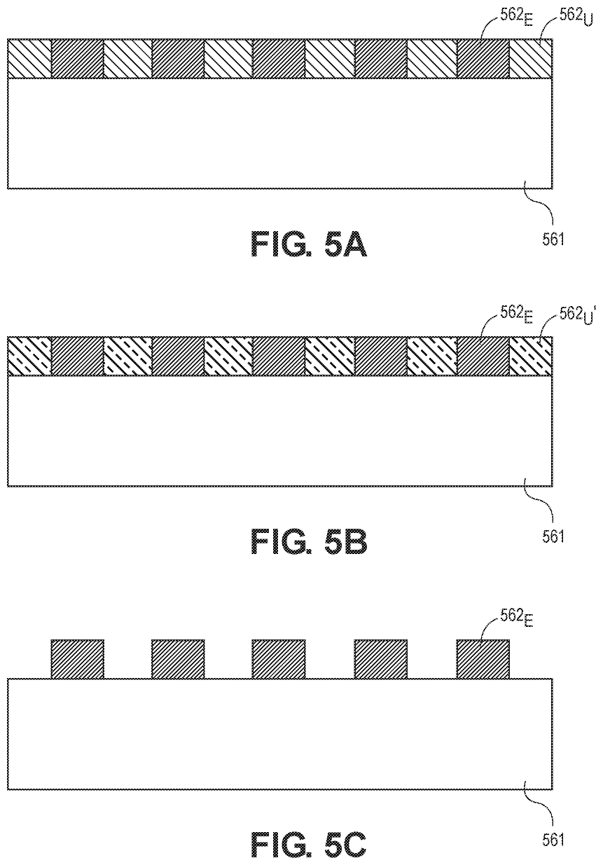

Referring now to FIG. 4, a flowchart describing a process 430 for patterning a metal oxo photoresist is shown, in accordance with an embodiment of the present disclosure. FIGS. 5A-5C are corresponding cross-sectional illustrations depicting various processing operations in process 430. In an embodiment, process 430 may be beneficial when the halogenating agent is not able to fully convert the unexposed regions of the photoresist into a volatile byproduct. Particularly, process 430 further includes vaporizing a protonated ligand into the vacuum chamber to convert unexposed regions of the photoresist into a volatile byproduct.

In an embodiment, process 430 may begin with operation 431, which includes providing a substrate with a metal oxo photoresist. In an embodiment, the substrate and metal oxo photoresist may be substantially similar to the substrate and metal oxo photoresist described above with respect to operation 221 of process 220.

In an embodiment, process 430 may continue with operation 432, which includes exposing portions of the metal oxo photoresist to create exposed regions and unexposed regions. In an embodiment, the exposure process of operation 432 may be substantially similar to the exposure process of operation 222 of process 220. FIG. 5A provides a cross-sectional illustration of the substrate 561 and exposed regions of the photoresist 562_{E} and unexposed regions of the photoresist 562_{U}.

In an embodiment, process 430 may continue with operation 433, which includes placing the substrate into a vacuum chamber. The vacuum chamber used in process 430 may be substantially similar to the vacuum chamber used in process 220.

In an embodiment, process 430 may continue with operation 434, which includes vaporizing a halogenating agent into the vacuum chamber. In an embodiment, the halogenating agent may react with the unexposed regions of the photoresist 562_{U} to provide a non-volatile product 562_{U}′. That is, in some embodiments, the halogenating agent, by itself, is not able to fully convert the unexposed regions of the photoresist 562_{U} into a volatile product that is removable from the vacuum chamber. In other embodiments, the halogenating agent may react with the exposed regions 562_{E} to produce a non-volatile product. In an embodiment, the non-volatile product 562_{U}′ may be a metal halide or a metal oxy halide with a chemical formula of MXₓ or MO_{y}Xₓ, where M is a metal or semimetal, X is a halide, x is 1-6 and y is 1-5.

In an embodiment, the halogenating agent is a metal halide with a formula MXₐ or MXₐL_{b}, where M is a metal or semimetal (e.g., Mo, W, Ta, Nb, Sn, V, Ti, or Si), X is a halide (e.g., Cl or Br), L is a volatile ligand (e.g., alkyls ethylenediamine, or Cp), a is 1-6 and b is 1-5. For example, the metal halide may include MoCl₅, TaCl₅, NbCl₅ or WCl₅.

In an additional embodiment, the halogenating agent is a metal oxy halide with a formula MOₐX_{b} or MOₐX_{b}L_{c}, where M is a metal or semimetal (e.g., Mo, W, Ta, Nb, Sn, V, Ti, or Si), X is a halide (e.g., Cl or Br), L is a volatile ligand (e.g., alkyls ethylenediamine, or Cp), a is 1-5, b is 1-5, and c is 1-5. For example, the metal oxy halide may include MoOCl₄, MoO₂Cl₂, WOCl₄, or WO₂Cl₂.

In yet another additional embodiment, the halogenating agent may be an organic halogenating agent. For example, the halogenating agent may include thionyl chloride (SOCl₂), methanesulfonyl chloride (CH₃SO₂Cl), trichloromethanesulfonyl chloride (CCl₃SO₂Cl), 4-toluenesulfonyl chloride (tosyl chloride), oxalyl chloride (ClCOCOCl), tert-butyl hypochlorite ((CH₃)₃COCl), N-chlorophthalimide, 1,3-dichloro-5,5-dimethylhydantoin, trimethylsilyl chloride, HCl, Cl₂, PCl₅, BCl₃, HBr, Br₂, CCl₃Br, CBr₄, 1,2-dibromo-1,1,2,2-tetrachloroethane (Cl₂CBrCBrCl₂), BBr₃, PBr₃, N-bromosuccinimide, N-bromoacetamide, 2-bromo-2-cyano-N,N-dimethylacetamide, 1,3-dibromo-5,5-dimethylhydantoin, 2,4,4,6-tetrabromo-2,5-cyclohexadienone, or trimethylsilyl bromide.

In an embodiment, the halogenating agent may be diluted with an inert gas. For example, inert gases such as Ar, N₂, or He may be used to dilute the halogenating agent. In other embodiments, gases such as O₂, N₂, CO₂, H₂, D₂, H₂O, D₂O, Ar, He, Cl₂, Br₂, HCl, HBr, CH₄, THMA-Me (where Me includes Sn, Zr, Al, Hf, Cr, Ta, Ru, Mo, Te, etc.), or combinations thereof may also be mixed with the halogenation agent. In an embodiment, the pressure may be between approximately 1 torr and approximately 100 torr. In a particular embodiment, the pressure may be between approximately 5 torr and approximately 10 torr. In an additional embodiment, the flow rate of gases may be between 1 sccm and 2,000 sccm, and a pressure may be between 1 mTorr and 500 mTorr. For example, the temperature may vary between approximately −90° C. and approximately 350° C. In a particular embodiment, the temperature may vary between approximately −90° C. and approximately −60° C. In an embodiment, source power may range between OW and 3,000 W using ICP, CCP, or TCP tools. In an embodiment, bias power may be between OW and 1,000 W at frequencies of approximately 13 MHz or approximately 2 MHz, for example.

In an embodiment, operation 434 may be implemented through the use of two or more sub-operations, similar to embodiments described in greater detail above. For example, a first sub-operation and a second sub-operation may include different processing parameters, such as, but not limited to, duration, pressure, temperature, and gas ratios. In other embodiments, the sub-operations may be looped for any number of cycles in order to complete operation 434.

In an embodiment, process 430 may continue with operation 435, which includes purging the vacuum chamber with an inert purge. In an embodiment, the purging process removes any byproducts and unreacted halogenating agent.

In an embodiment, process 430 may continue with operation 436, which includes vaporizing a ligand into the vacuum chamber. In an embodiment, the ligand reacts with the non-volatile product 562_{U}′ to produce a volatile byproduct. That is, the reaction between the vaporized ligand and the non-volatile product 562_{U}′ results in the removal of the unexposed regions from the substrate 561, as shown in FIG. 5C. In cases when the non-volatile product is generated from the exposed regions 562_{E}, the exposed regions may be removed from the substrate 561. In an embodiment, the ligand is a protonated ligand, such as amine. In an embodiment, the ligand may be diluted with an inert gas such as Ar, N₂, or He. In an embodiment, the volatile byproduct may have the chemical formula MXₓLy or MO_{X}X_{y}L_{Z}, where M is a metal or semimetal (e.g., Mo, W, Ta, Nb, Sn, V, Ti, or Si), X is a halide (e.g., Cl or Br), L is a volatile ligand (e.g., amine), x is 1-5, y is 1-5, and z is 1-5.

In an embodiment, the pressure may be between approximately 1 torr and approximately 100 torr. In a particular embodiment, the pressure may be between approximately 5 torr and approximately 10 torr. In an additional embodiment, the flow rate of gases may be between 1 sccm and 2,000 sccm, and a pressure may be between 1 mTorr and 500 mTorr. In an embodiment, the substrate 561 may have a controlled temperature during operation 436. For example, the temperature may vary between approximately −90° C. and approximately 350° C. In a particular embodiment, the temperature may vary between approximately −90° C. and approximately −60° C. In an embodiment, source power may range between OW and 3,000 W using ICP, CCP, or TCP tools. In an embodiment, bias power may be between OW and 1,000 W at frequencies of approximately 13 MHz or approximately 2 MHz, for example.

In an embodiment, operation 436 may be implemented through the use of two or more sub-operations, similar to embodiments described in greater detail above. For example, a first sub-operation and a second sub-operation may include different processing parameters, such as, but not limited to, duration, pressure, temperature, and gas ratios. In other embodiments, the sub-operations may be looped for any number of cycles in order to complete operation 436.

In an embodiment, process 430 may continue with operation 437, which includes purging the vacuum chamber. Purging with an inert gas may result in the removal of volatile byproducts and remaining vaporized ligands.

In an embodiment, operations 434-437 may define a cycle. The cycle may be repeated any number of times in order to fully (or substantially) remove the unexposed regions 562_{U} of the metal oxo photoresist. For example, a cycle may include a sequence including a pulse of a vaporized halogenating agent being introduced into the vacuum chamber, followed by an inert purge, followed by a pulse of a vaporized ligand being introduced into the vacuum chamber, followed by an inert purge. In other embodiments, a single cycle may be used. In such embodiments, a soak of the vaporized halogenating agent may be introduced into the vacuum chamber, followed by an inert purge, followed by a soak of a vaporized ligand into the vacuum chamber, followed by an inert purge.

Generally, it has been shown that the etch selectivity of the unexposed regions of the photoresist 562_{U} relative to the exposed regions of the photoresist 562_{E} increases with increases in pressure. Additionally, it has been generally shown that increased substrate temperatures during one or more of operations 434-437 provide an increase in the etch selectivity of the unexposed regions of the photoresist 562_{U} relative to the exposed regions of the photoresist 562_{E}.

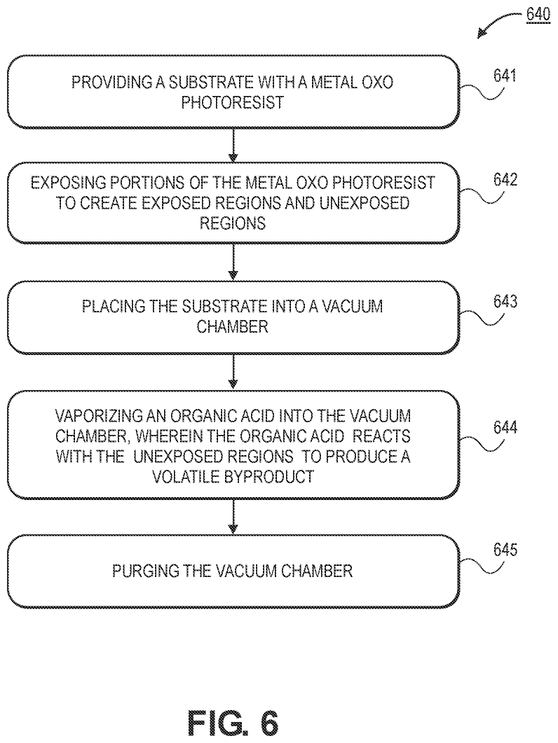

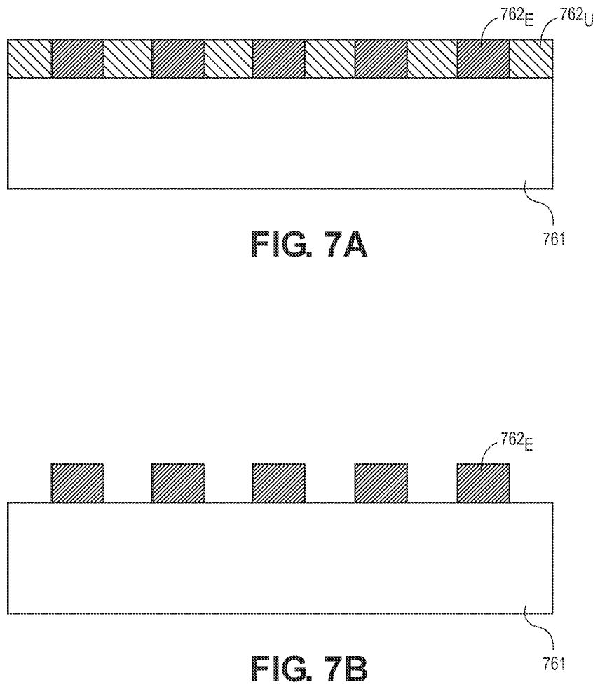

Referring now to FIG. 6, a flowchart describing a process 640 for patterning a metal oxo photoresist is shown, in accordance with an embodiment of the present disclosure. FIGS. 7A-7B are corresponding cross-sectional illustrations depicting various processing operations in process 640. In an embodiment, process 640 may be similar to the process 220, with the exception that the halogenating agent is replaced with a vaporized organic acid. That is, an organic acid is vaporized to a vacuum chamber, where the organic acid reacts with either the unexposed or exposed regions of the metal oxo photoresist to produce a volatile byproduct.

In an embodiment, process 640 may begin with operation 641, which includes providing a substrate with a metal oxo photoresist. In an embodiment, the substrate and metal oxo photoresist may be substantially similar to the substrate and metal oxo photoresist described above with respect to operation 221 of process 220.

In an embodiment, process 640 may continue with operation 642, which includes exposing portions of the metal oxo photoresist to create exposed regions and unexposed regions. In an embodiment, the exposure process of operation 642 may be substantially similar to the exposure process of operation 222 of process 220. FIG. 7A provides a cross-sectional illustration of the substrate 761 and exposed regions of the photoresist 762_{E} and unexposed regions of the photoresist 762_{U}.

In an embodiment, process 640 may continue with operation 643, which includes placing the substrate into a vacuum chamber. The vacuum chamber used in process 640 may be substantially similar to the vacuum chamber used in process 220.

In an embodiment, process 640 may continue with operation 644, which includes vaporizing an organic acid into the vacuum chamber. In an embodiment, the organic acid reacts with either the unexposed regions 762_{U} or the exposed regions 762_{E} to produce a volatile byproduct. That is, the reaction between the organic acid and the unexposed regions 762_{U} results in the removal of the unexposed regions 762_{U} from the substrate 761 (as shown in FIG. 7B), or the reaction between the organic acid and the exposed regions 762_{E} results in the removal of the exposed regions 762_{E} from the substrate 761.

In an embodiment, the organic acid may be a carboxylic acid with a chemical formula RCO₂H. For example, R may be H, CH₃, tBu, or iPr. In an embodiment, the byproduct of the reaction is a volatile carboxylate. For example, the carboxylate may have a chemical formula M(RCO₂)ₓ, where M is the metal from the metal oxo photoresist and R is the R used in the organic acid.

In an embodiment, the organic acid may be diluted with an inert gas. For example, inert gases such as Ar, N₂, or He may be used to dilute the organic acid. In other embodiments, gases such as O₂, N₂, CO₂, H₂, D₂, H₂O, D₂O, Ar, He, Cl₂, Br₂, HCl, HBr, CH₄, THMA-Me (where Me includes Sn, Zr, Al, Hf, Cr, Ta, Ru, Mo, Te, etc.), or combinations thereof may also be mixed with the organic acid. Generally, it has been shown that the etch selectivity of the unexposed regions of the photoresist 762_{U} relative to the exposed regions of the photoresist 762_{E} increases with increases in pressure. In an embodiment, the pressure may be between approximately 1 torr and approximately 100 torr. In a particular embodiment, the pressure may be between approximately 5 torr and approximately 10 torr.

In an embodiment, the substrate 761 may have a controlled temperature during operation 644. For example, the temperature may vary between approximately −90° C. and approximately 350° C. In a particular embodiment, the temperature may vary between approximately −90° C. and approximately −60° C. In an embodiment, source power may range between OW and 3,000 W using ICP, CCP, or TCP tools. In an embodiment, bias power may be between OW and 1,000 W at frequencies of approximately 13 MHz or approximately 2 MHz, for example.

In an embodiment, operation 644 may be implemented through the use of two or more sub-operations, similar to embodiments described in greater detail above. For example, a first sub-operation and a second sub-operation may include different processing parameters, such as, but not limited to, duration, pressure, temperature, and gas ratios. In other embodiments, the sub-operations may be looped for any number of cycles in order to complete operation 644.

In an embodiment process 640 may continue with operation 645 which includes purging the vacuum chamber. Purging the vacuum chamber removes the byproducts from the reaction in operation 644 from the vacuum chamber. In an embodiment, operation 644 may be implemented as a soak followed by a single purge in operation 645. In alternative embodiments, operations 644 and 645 may define a cycle including a pulse of the organic acid followed by a purge. In such embodiments, a plurality of cycles may be repeated in order to clear the unexposed regions of the photoresist 762_{U}.

Accordingly, embodiments described herein include thermal vapor phase processes for developing a metal oxo photoresist. As such, embodiments disclosed herein may not require vacuum chambers with the ability to form a plasma. The removal of a plasma process also reduces damage to the metal oxo photoresist. This is especially beneficial at low photoresist thicknesses (e.g., at photoresist thicknesses of approximately 15 nm or smaller). At low photoresist thicknesses plasma damage may result in poor LER/LWR or even broken line patterns when the pattern is transferred into the underlayer.

Additionally, wet chemistries are avoided, and byproducts generated by the reactions disclosed herein may be destroyed with abatement systems typical of the semiconductor manufacturing industry. As such, waste streams are significantly reduced. Furthermore, vapor phase processes allow for fewer defects and impurities in the resulting developed metal oxo photoresist, especially at small feature sizes, since wet chemistries are not used.

FIG. 8A is a schematic of a vacuum chamber configured to develop the unexposed regions of a metal oxo photoresist, in accordance with an embodiment of the present disclosure. Vacuum chamber 800 includes a grounded chamber 805. In an embodiment, the chamber 805 may be temperature controlled. That is, walls of the chamber 805 may be actively cooled or heated during processes disclosed herein. A substrate 810 is loaded through an opening 815 and positioned on a temperature controlled pedestal 820.

Process gases, are supplied from gas sources 844 through respective mass flow controllers 849 to the interior of the chamber 805. In certain embodiments, a gas distribution plate 835 provides for distribution of process gases 844, such as, for example, halogenating agents, ligands, organic acids, and/or inert gases. Chamber 805 is evacuated via an exhaust pump 855.

The vacuum chamber 800 is controlled by controller 870. The controller 870 may include a CPU 872, a memory 873, and an I/O interface 874. The CPU 872 may execute processing operations within the vacuum chamber 800 in accordance with instructions stored in the memory 873. For example, one or more processes such as processes 220, 430, and 740 described above may be executed in the vacuum chamber by the controller 870.

While the vacuum chamber 800 is described above as not having features suitable for forming a plasma within the chamber, it is to be appreciated that embodiments of the present disclosure may be implemented in a vacuum chamber 800 that is capable of generating a plasma within the chamber.

Referring now to FIG. 8B, a plan view schematic illustration of a cluster tool 800 is shown, in accordance with an embodiment. In an embodiment, the cluster tool 800 may include a load port 892. The load port 892 may be configured to receive one or more front opening unified pods (FOUPs) that include a plurality of substrate 861. The substrates 861 may be retrieved by a robot 895 that is positioned in a central transfer chamber of the cluster tool 800. The robot 895 may distribute the substrates 861 between an aligner 896 and one or more processing chamber 890. The processing chambers 890 may include vacuum chambers in order to implement dry deposition and/or dry developing processes for metal oxo layers on the substrates 861, similar to embodiments described in greater detail above. For example, a first chamber 890 may deposit the metal oxo resist on the substrate 861, a second chamber 890 may expose the metal oxo resist to EUV radiation to form a latent image in the metal oxo resist, and a third chamber 890 may be used to pre-treat and/or post-treat the metal oxo resist. A chamber 890 may also be used to develop the metal oxo resist. In some embodiments, the cluster tool 800 may further include a chamber for depositing an underlayer. The cluster tool 800 may further include a chamber to perform a post exposure bake process after the EUV exposure tool exposes the metal oxo resist to form the latent image in the metal oxo resist. As such, the entire process (from deposition to final post treatment) may be implemented in a single processing environment (e.g., tool 800).

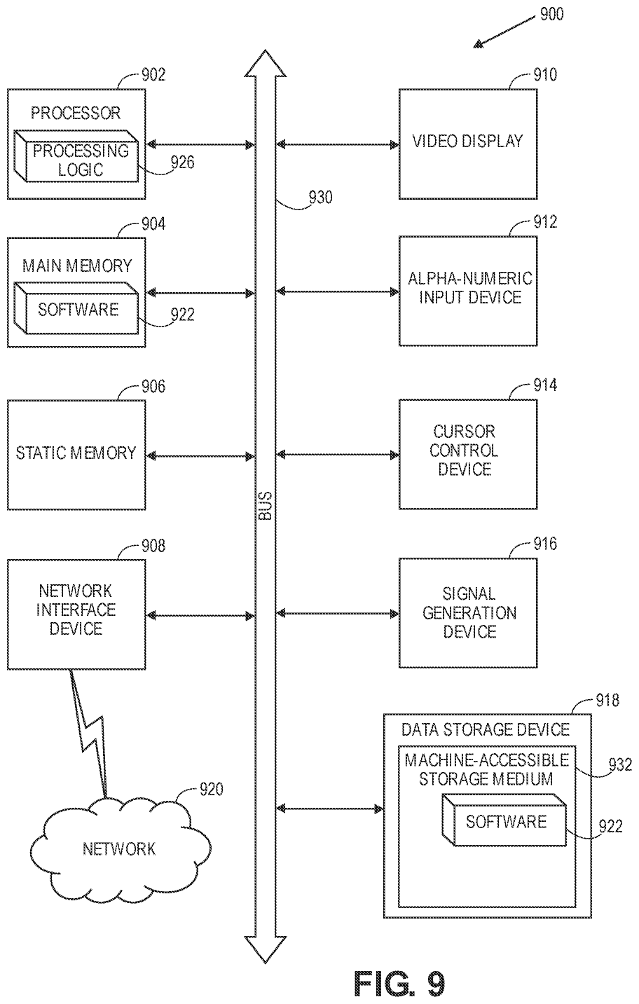

FIG. 9 illustrates a diagrammatic representation of a machine in the exemplary form of a computer system 900 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 900 includes a processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), MRAM, etc.), and a secondary memory 918 (e.g., a data storage device), which communicate with each other via a bus 930.

Processor 902 represents one or more general-purpose processing devices such as a microprocessor, central processing unit, or the like. More particularly, the processor 902 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 902 may also be one or more special-purpose processing devices such as an application specific integrated circuit (ASIC), a field programmable gate array (FPGA), a digital signal processor (DSP), network processor, or the like. Processor 902 is configured to execute the processing logic 926 for performing the operations described herein.

The computer system 900 may further include a network interface device 908. The computer system 900 also may include a video display unit 910 (e.g., a liquid crystal display (LCD), a light emitting diode display (LED), or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium (or more specifically a computer-readable storage medium) 932 on which is stored one or more sets of instructions (e.g., software 922) embodying any one or more of the methodologies or functions described herein. The software 922 may also reside, completely or at least partially, within the main memory 904 and/or within the processor 902 during execution thereof by the computer system 900, the main memory 904 and the processor 902 also constituting machine-readable storage media. The software 922 may further be transmitted or received over a network 920 via the network interface device 908.

While the machine-accessible storage medium 932 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of developing a metal oxo photoresist on a substrate with vapor phase processes. The method includes exposing a metal oxo photoresist to provide exposed and unexposed regions, and placing a substrate with the exposed photoresist into a vacuum chamber. In an embodiment, a gas reactive to the unexposed regions of the photoresist is vaporized into the vacuum chamber. For example, the reactive gas may include one or more of a halogenating agent, a ligand, and an organic acid. The reactive gas and the unexposed regions of the metal oxo photoresist react to form a volatile byproduct. The byproduct may be removed from the chamber with an inert gas purge.

Thus, methods for forming a developing a metal oxo photoresist using vapor phase processes have been disclosed.

What is claimed is:

1. A method for developing a photopatterned metal oxo photoresist, comprising:
pre-treating the photopatterned metal oxo photoresist with a pre-treatment process;
developing the photopatterned metal oxo photoresist with a thermal dry develop process to selectively remove a portion of the photopatterned metal oxo photoresist and form a resist mask, wherein the thermal dry develop process comprises:
a first sub-operation; and
a second sub-operation, wherein the first sub-operation is different than the second sub-operation; and
post-treating the resist mask with a post-treatment process.

2. The method of claim 1, wherein the first sub-operation has a first duration that is different than a second duration of the second sub-operation.

3. The method of claim 2, wherein the first duration is 60 seconds or more, and wherein the second duration is 30 seconds or less.

4. The method of claim 1, wherein the first sub-operation has a first pressure and the second sub-operation has a second pressure that is different than the first pressure.

5. The method of claim 4, wherein the first pressure and the second pressure are between 20 mTorr and 350 mTorr.

6. The method of claim 1, wherein the first sub-operation has a first temperature and the second sub-operation has a second temperature that is different than the first temperature.

7. The method of claim 6, wherein the first temperature and the second temperature are between −90 degrees Celsius and 350 degrees Celsius.

8. The method of claim 1, wherein the first sub-operation has a first gas ratio and the second sub-operation has a second gas ratio that is different than the first gas ratio.

9. The method of claim 8, wherein the first gas ratio and the second gas ratio are ratios of HBr to Ar.

10. The method of claim 1, further comprising:
repeating the first sub-operation and the second sub-operation for a plurality of cycles.

11. The method of claim 1, wherein the pre-treatment process and the post-treatment process comprises a thermal treatment, an irradiation treatment, and/or a plasma treatment.

12. The method of claim 11, wherein the post-treatment process is the same as the pre-treatment process.

13. The method of claim 11, wherein the post-treatment process is different than the pre-treatment process.

14. The method of claim 1, wherein the thermal dry development process includes a development chemistry comprising a halogenation agent and an inert gas.

15. The method of claim 14, wherein the development chemistry comprising at least one gas of O₂, N₂, CO₂, CO, H₂, D₂, H₂O, D₂O, Ar, He, Cl₂, Br₂, HCl, HBr, CH₄, TDMA-Me, and NH₄Cl.

16. A semiconductor processing tool, comprising:
a transfer chamber, wherein a substrate handling robot is provided in the transfer chamber;
a first processing chamber fluidically coupled to the transfer chamber, wherein the first processing chamber is configured to deposit a metal oxo resist on a substrate with a dry deposition process;
a second processing chamber fluidically coupled to the transfer chamber, wherein the second processing chamber is configured to pre-treat or post-treat the metal oxo resist with a thermal treatment, an irradiation treatment, and/or a plasma treatment; and
a third processing chamber fluidically coupled to the transfer chamber, wherein the third processing chamber is configured to develop the metal oxo resist with a dry develop process, wherein the dry develop process comprises:
a first sub-operation; and
a second sub-operation that is different than the first sub-operation.

17. The semiconductor processing tool of claim 16, further comprising:
an extreme ultraviolet (EUV) exposure tool coupled to the transfer chamber, wherein the EUV exposure tool exposes the metal oxo resist to form a latent image in the metal oxo resist.

18. The semiconductor processing tool of claim 16, further comprising:
a fourth process chamber coupled to the transfer chamber, wherein the fourth process chamber is configurated to deposit an underlayer on the substrate, wherein the underlayer comprises a high Z metal oxide.

19. The semiconductor processing tool of claim 16, further comprising: a fifth process chamber coupled to the transfer chamber, wherein the fifth process chamber is configurated to perform a post exposure bake process after the EUV exposure tool exposes the metal oxo resist to form the latent image in the metal oxo resist.

20. The semiconductor processing tool of claim 16, wherein the dry develop process is performed with a development chemistry at a temperature between −90 degrees Celsius and 350 degrees Celsius, wherein the development chemistry renders a portion of the metal oxo photoresist volatile.
